(19) United States
(12) Patent Application Publication
(10) Pub. No.: US 2008/0211541 A1
(43) Pub. Date: Sep. 4, 2008

(54) Precision voltage level shifter based on thin gate oxide transistors

(75) Inventor: Rajat Chauhan, Dehradun (IN)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/893,637

(22) Filed: Aug. 16, 2007

(30) Foreign Application Priority Data
Mar. 2, 2007 (IN) 431/CHE/2007

(51) Int. Cl. H03K 19/0175

(52) U.S. Cl. 326/68

(57) ABSTRACT

A precision voltage level shifter based on thin gate oxide transistors is disclosed. A method of a voltage level shifter includes serially connecting thin n-channel gate oxide semiconductor FETs to think n-channel gate oxide semiconductor FETs to enable the voltage level shifter with a low input voltage. The method further includes permanently turning on a thick p-channel gate oxide semiconductor FET through grounding a gate of the thick p-channel gate oxide semiconductor FET to enable the voltage level shifter with an input voltage close to the I/O voltage of the voltage level shifter.

### CLAIM OF PRIORITY

This patent application claims priority to India Provisional Patent Application No. 431/CHE/2007, titled ‘A Voltage Level Shifter to Level-Shift Low Voltage Level Signal to High Voltage Levels’ filed with Indian Patent Office on Mar. 2, 2007.

### FIELD OF TECHNOLOGY

This disclosure relates generally to technical fields of electronic circuit and, in one embodiment, to a precision voltage level shifter based on thin gate oxide transistors.

### BACKGROUND

A core of a semiconductor chip may be operated at a low voltage level (e.g., a core voltage) while an I/O interface of the semiconductor chip may work at a high voltage level (e.g., an I/O voltage). In order to translate from the low voltage level to the high voltage level or vice versa, a voltage level shifter may be employed in the semiconductor chip.

In an embodiment of U.S. Pat. No. 5,422,523, a circuitry was used in the voltage level shifter to minimize power dissipation due to direct current. US Patent Application 2005237084 points out shortcomings of U.S. Pat. No. 5,422,523—namely degradation in the performance of the voltage level shifter when the difference between the core voltage and the I/O voltage is large. To remedy the problem, US Patent Application 2005237084 proposes an addition of a latch circuit and a feedback circuit along with a common input node.

FIG. 1 shows a prior art voltage level shifter that is an embodiment of US Patent Application 200523784, the disclosure hereby incorporated by reference. The circuit of FIG. 1 fails to work when the difference between the core voltage (e.g., an input voltage 102) and the I/O voltage (e.g., a V_{dds} 104) are too close to each other (e.g., the input voltage 102=1.2 volts and the V_{dds} 104=1.5 volts) and/or the core voltage is too low.

For example, the input voltage 102 is set at 1.2 volts and the V_{dds} 104 is set at 1.5 volts. However, supply variations can cause the input voltage 102 to go as high as 1.32 volts and the V_{dds} to go as low as 1.35 volts. In this condition, the voltage level shifter 100 may not work when the input voltage 102 (e.g., the core voltage) transitions from low to high. In FIG. 1, a PMOS 1 108 is turned on and the NMOS 1 110 is turned off when the input voltage 102 is low.

Thus, a X node 112 is charged to close to the V_{dds} 104 (e.g., 1.35 volts) as there is a short circuit formed between the V_{dds} 104 and the X node 112 and an open circuit formed between the X node 112 and the ground 106. The low voltage (e.g., 0 volt) passed through an inverter 1 114 (e.g., which may be the only component of the voltage level shifter 100 powered by the core voltage of 1.32 volts) becomes high, thus turning on the NMOS 2 116. As the NMOS 2 116 is turned on and a PMOS 2 118 is turned off, an output voltage 120 is discharged to ground, thus maintaining its logic as low. While the output voltage 120 is maintained at the low voltage, a latch 122 (e.g., made of an inverter 2 124 and an inverter 3 126) produces a feedback signal 128 which turns on a NMOS 3 130, thus forming a current path to the ground 106 with the source node of the NMOS 1 110.

When the input voltage 102 makes a transition from the low voltage to a high voltage (e.g., 1.32 volts), the PMOS 1 108 is turned off and the NMOS 1 110 is turned on. This may cause the X node 112 to discharge to the ground 106 through a current path formed between the X node 112 and the ground 106. This in turn turns on the PMOS 2 118 and turns off the NMOS 2 116, thus charging the output voltage 120 close to the V_{dds} 104 (e.g., 1.35 volts). The feedback signal 128 (e.g., the low voltage) turns off the NMOS 3 130, thus causing the X node 112 to float. Because of the small voltage difference (e.g., 0.03 volt) between the V_{dds} 104 and the input voltage 102, the PMOS 1 108 is not even partially on, thus continuously causing the X node 112 to float. With the X node 112 floating, the real purpose of the voltage level shifter 100 may be lost as the X node 112 is required to go high (e.g., when the PMOS 1 108 is partially on, thus slowly charging the X node 112 to high) to turn off the PMOS 2 118.

Additionally, the NMOS 1 110 and the NMOS 2 116 may fail to turn on when the input voltage 102 is not large enough (e.g., less than 0.9 volts). This may be due to the threshold voltage of a MOS transistor directly proportional to the thickness of the gate oxide of the MOS transistor. Because the NMOS 1 110 and the NMOS 2 116 are thick oxide transistors, they may not be turned on when the input voltage 102 (e.g., less than 0.9 volt) is less than a threshold voltage of either the NMOS 1 110 and the NMOS 2 116.

### SUMMARY

A precision voltage level shifter based on thin gate oxide transistors is disclosed. In one aspect, a voltage level shifter includes one or more gate oxide semiconductor field effect transistors (FETs) to translate an input voltage to an output voltage (e.g., a number of thin gate oxide semiconductor FETs of the one or more gate oxide semiconductor FETs to connect with a number of thick gate oxide semiconductor FETs of the one or more gate oxide semiconductor FETs).

The one or more gate oxide semiconductor FETs of the voltage level shifter may comprise one or more p-channel gate oxide semiconductor FETs or one or more n-channel gate oxide semiconductor FETs. The number of thin gate oxide semiconductor FETs may enable the voltage level shifter to perform with the input voltage approximately at 0.9 volt. The voltage level shifter may further include a feedback loop to connect the output voltage of the voltage level shifter to one of the one or more gate oxide semiconductor FETs to minimize power dissipation in the voltage level shifter.

Additionally, the voltage level shifter may include one or more pairs of thick gate oxide semiconductor FETs connected to the voltage level shifter with their gates connected to a low voltage supply to increase a limit of the output voltage. The low voltage supply may supply 1 volt and the limit of the output voltage may be 2.5 volts.

In another aspect, a circuit includes a first transistor group having a thick p-channel gate oxide FET, a thick n-channel gate oxide FET, and a thin n-channel gate oxide FET in series (e.g., where a gate of the thin n-channel gate oxide FET is connected to an input voltage, and a gate of the thick p-channel oxide FET is connected to a ground voltage) and a second transistor group having a thick p-channel gate oxide FET, a thick n-channel gate oxide FET, and a thin n-channel gate oxide FET in series (e.g., where a gate of the thin n-channel gate oxide FET is connected to an inverse of the input voltage, a drain of the thick p-channel gate oxide FET of the first transistor group is connected to a gate of the thick p-channel gate oxide FET of the second transistor group, and a gate of the thick n-channel gate oxide FET is connected to an I/O voltage).

The circuit further includes a third transistor group having a thick p-channel gate oxide FET (e.g., where a drain of the thick p-channel gate oxide FET is connected to a drain of the thick p-channel gate oxide FET of the second transistor group, and a gate of the thick p-channel gate oxide FET is connected to a feedback signal of the circuit) and a feedback loop to connect the feedback signal to a gate of the thick n-channel gate oxide FET of the first transistor group.

The circuit may have the I/O voltage of 1.8 volt and the input voltage of no less than 0.9 volt. The gate of the thick p-channel gate oxide FET of the first transistor group may be connected to the ground voltage to enable the circuit to have the input voltage close to the I/O voltage. The thin n-channel gate oxide FET of the first transistor group and the thin n-channel gate oxide FET of the second transistor group may allow the circuit to have the input voltage of 0.9 volt.

The circuit may also include a first inverter to inversely convert the input voltage to feed to the gate of the thin n-channel gate oxide FET of the second transistor group. The circuit may further include second inverter to inversely convert a voltage obtained at the drain of the thick p-channel gate oxide FET of the second transistor group. In addition, the circuit may include a third inverter to inversely convert the feedback signal to generate the output voltage. Moreover, the circuit may include a pair of additional thick n-channel gate oxide FETs added to the circuit to increase the I/O voltage.

Additionally, the circuit may include a low voltage supply (e.g., which supplies 1 volt to the gates of the pair of additional thick n-channel gate oxide FETs) to connect to gates of the pair of additional thick n-channel gate oxide FETs. The pair of additional thick n-channel gate oxide FETs may increase the I/O voltage up to 2.5 volts without aging the thin n-channel gate oxide FETs. Also, the circuit may replace the thick p-channel gate oxide FET of the first transistor group with one or more resistors.

In yet another aspect, a method of a voltage level shifter includes serially connecting thin n-channel gate oxide semiconductor FETs to thick n-channel gate oxide semiconductor FETs to enable the voltage level shifter with a low input voltage. The method further includes permanently turning on a thick p-channel gate oxide semiconductor FET through grounding a gate of the thick p-channel gate oxide semiconductor FET to enable the voltage level shifter with an input voltage close to an I/O voltage of the voltage level shifter.

The method may further include connecting additional thick n-channel oxide semiconductor FETs in series with the thin n-channel gate oxide semiconductor FETs to increase an output voltage of the voltage level shifter.

The methods, systems, and apparatuses disclosed herein may be implemented in any means for achieving various aspects, and may be executed in a form of a machine-readable medium embodying a set of instructions that, when executed by a machine, cause the machine to perform any of the operations disclosed herein. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 2 is a voltage level shifter which works well with a small voltage difference between a core voltage and an I/O voltage and even when the core voltage is low, according to one embodiment.

FIG. 3 is a voltage level shifter which works with the I/O voltage being high while maintaining the benefits of the voltage level shifter of FIG. 2, according to one embodiment.

FIG. 4 is process flow chart of connecting gate oxide semiconductor FETs to enable a voltage level shifter with a wide range of input voltage, according to one embodiment.

Other features of the present embodiments will be apparent from the accompanying drawings and from the detailed description that follows.

### DETAILED DESCRIPTION

A precision voltage level shifter based on thin gate oxide transistors is disclosed. In the following description, for purposes of explanation, numerous specific details are set forth in order to provide a thorough understanding of the various embodiments. It will be evident, however, to one skilled in the art that the various embodiments may be practiced without these specific details.

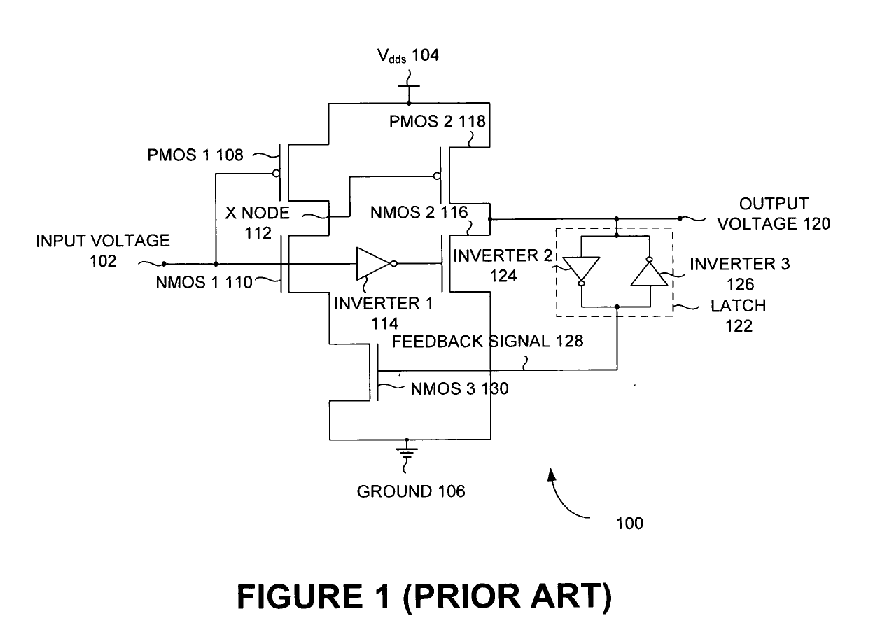

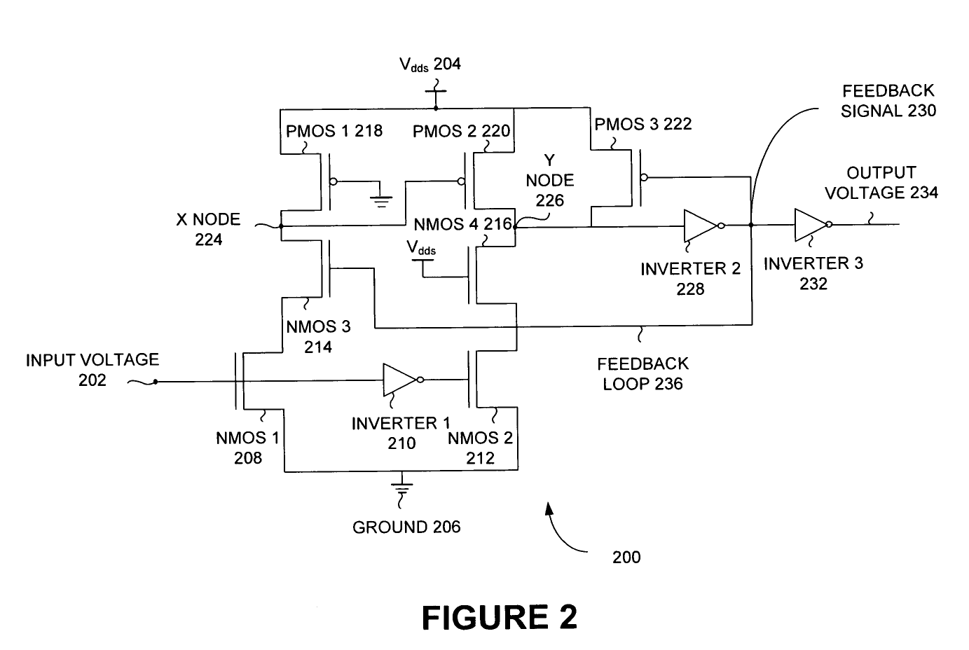

In one embodiment, a voltage level shifter (e.g., the voltage level shifter 200 of FIG. 2) includes one or more gate oxide semiconductor field effect transistors (FETs) to translate an input voltage (e.g., an input voltage 202) to an output voltage (e.g., an output voltage 234).

In another example embodiment, a circuit includes (e.g., the voltage level shifter 202) a first transistor group having a thick p-channel gate oxide FET (e.g., a PMOS 1 218), a thick n-channel gate oxide FET (e.g., a NMOS 3 214), and a thin n-channel gate oxide FET (e.g., a NMOS 1 208) in series and a second transistor group having a thick p-channel gate oxide FET (e.g., a PMOS 2 220), a thick n-channel gate oxide FET (e.g., a NMOS 4 216), and a thin n-channel gate oxide FET (e.g., a NMOS 2 212) in series. The circuit further includes a third transistor group having a thick p-channel gate oxide FET (e.g., a PMOS 3 222) and a feedback loop (e.g., a feedback loop 236) to connect a feedback signal (e.g., a feedback signal 230) to a gate of the thick n-channel gate oxide FET of the first transistor group (e.g., the NMOS 3 214).

In yet another example embodiment, a method of a voltage level shifter includes serially connecting thin n-channel gate oxide semiconductor FETs to thick n-channel gate oxide semiconductor FETs to enable the voltage level shifter with a low input voltage. The method further includes permanently turning on a thick p-channel gate oxide semiconductor FET through grounding a gate of the thick p-channel gate oxide semiconductor FET to enable the voltage level shifter with an input voltage close to an I/O voltage of the voltage level shifter.

FIG. 2 is a voltage level shifter 200 which works well with a small voltage difference between a core voltage and an I/O voltage and even when the core voltage is low, according to one embodiment. In FIG. 2, a NMOS 1 208 and a NMOS 2 212 are thin gate oxide semiconductor field effect transistors, and an inverter 1 210 is an inverter operating at low voltage supply (e.g., the core voltage). A NMOS 3 214 and a NMOS 4 216 are thick gate oxide semiconductor field effect transistors, and a PMOS 1 218, a PMOS 2 220, and a PMOS 3 222 are also thick gate oxide semiconductor field effect transistors. An inverter 2 228 operates at high voltage supply (e.g., the I/O voltage).

In FIG. 2, a first transistor group includes a NMOS 1 208, a NMOS 3 214, and a PMOS 1 218, in series. A gate of the NMOS 1 208 is connected to an input voltage 202, and a gate of the PMOS 1 218 is connected to a ground voltage 206. A second transistor group includes a NMOS 2 213, a NOMS 4 216, and a PMOS 2 220 in series. A gate of the NMOS 2 212 is connected to an inverse of the input voltage 202, a drain of the PMOS 1 218 is connected to a gate of the PMOS 2 220, and a gate of the NMOS 4 216 is connected to an I/O voltage (e.g., V_{dds} 204).

A third transistor group includes a PMOS 3 222 with a drain of the PMOS 3 222 is connected to a drain of PMOS 2 220, and a gate of the PMOS 3 222 is connected to a feedback signal 230 of the voltage level shifter 200. A feedback loop 336 connects the feedback signal 330 to a gate of the NMOS 3 314.

In one example embodiment, the V_{dds} 204 is 1.8 volts and the input voltage 202 is 1 volt. When the input voltage 202 is low, the NMOS 1 208 (e.g., a thin gate oxide semiconductor field effect transistor) is off and the NMOS 2 212 (e.g., another thin oxide semiconductor field effect transistor) is on. Because the PMOS 1 218 is always on, the X node 224 is charged to high with the V_{dds} 204. The high voltage (e.g., 1.8 volts) at the X node 224 turns off the PMOS 2 220. Because the NMOS 2 212 and the NMOS 4 216 are turned on, the Y node 226 goes to low, thus resulting in low (e.g., 0 volt) as an output voltage 234.

The NMOS 3 214 and the NMOS 4 216 (e.g., the thick gate oxide semiconductor field effect transistors) protect the NMOS 1 208 and the NMOS 2 212 (e.g., the thin gate oxide field effect transistors) respectively from seeing the full V_{dds} (e.g., 1.8 volts). Each of the NMOS 3 214 and the NMOS 4 216 drops the voltage at the drain of the NMOS 1 208 and the NMOS 2 212 by the threshold voltage of the NMOS 1 208 and the NMOS 2 212 respectively, and does not allow the voltage at the drain to go over V_{dds}—the threshold voltage (e.g., which may be approximately 1.2 volts).

When the input voltage 202 switches from low (e.g., 0 volt) to high (e.g., 1 volt), the NMOS 1 208 is turned on while the NMOS 2 212 is turned off. As the NMOS 4 216 is tuned on and the NMOS 3 214 is still on, a current path is created through the NMOS 1 208, the NMOS 3 214, and the PMOS 1 218, and the X node 224 is pulled low turning on the PMOS 2 220. The PMOS 1 218 is kept comparatively weak so that the NMOS 1 208 and the NMOS 3 214 can pull the X node 224 low enough to turn on the PMOS 2 220.

The NMOS 2 212 is already off, so the PMOS 2 220 pulls up the Y node 226 to the V_{dds} (e.g., 1.8 volts), thus transitioning the output voltage 234 from low to high. The feedback signal 230 (e.g., low) turns on the PMOS 3 222, and turns off the NMOS 3 214. The PMOS 3 222 is kept weak to just hold the Y node 226 high. When the NMOS 3 214 is turned off, the current path through the NMOS 1 208, the NMOS 3 214, and the POMS 1 218 is no longer present. As the result, the X node 224 is pulled up to high (e.g., 1.8 volts), which in turns switch off the PMOS 2 220. The Y node 226 is held high through the PMOS 3 222 (e.g., which is kept weak).

When the input voltage 202 transitions from high to low, the NMOS 1 208 is turned off, but the NMOS 2 212 is turned on. The X node 224 remains high, thus keeping the PMOS 2 220 off. The Y node 226 is pulled down to low as the NMOS 2 212 is on and the PMOS 3 222 is kept weak. The feedback signal 230 (e.g., high) turns off the PMOS 3 222 and turns on the NMOS 3 214.

It is appreciated that the voltage level shifter 200 works well even when the input voltage 202 is as low as 0.9 volt because the NMOS 1 208 and the NMOS 2 212 are thin gate oxide semiconductor field effect transistors with a low threshold value. Additionally, as the PMOS 1 218 is kept permanently on instead of being driven by the input voltage 202, the voltage level shifter 200 performs well even when the core voltage (e.g., the input voltage 202) is close to the I/O voltage (e.g., the V_{dds} 204). Nevertheless, the V_{dds} 204 of the voltage level shifter 200 may not go higher than 1.8 volts because the NMOS 1 208 and the NMOS 2 212 may result in an early aging as the thin oxide gate semiconductor field effect transistors allow only up to 1 volt across their gate oxide.

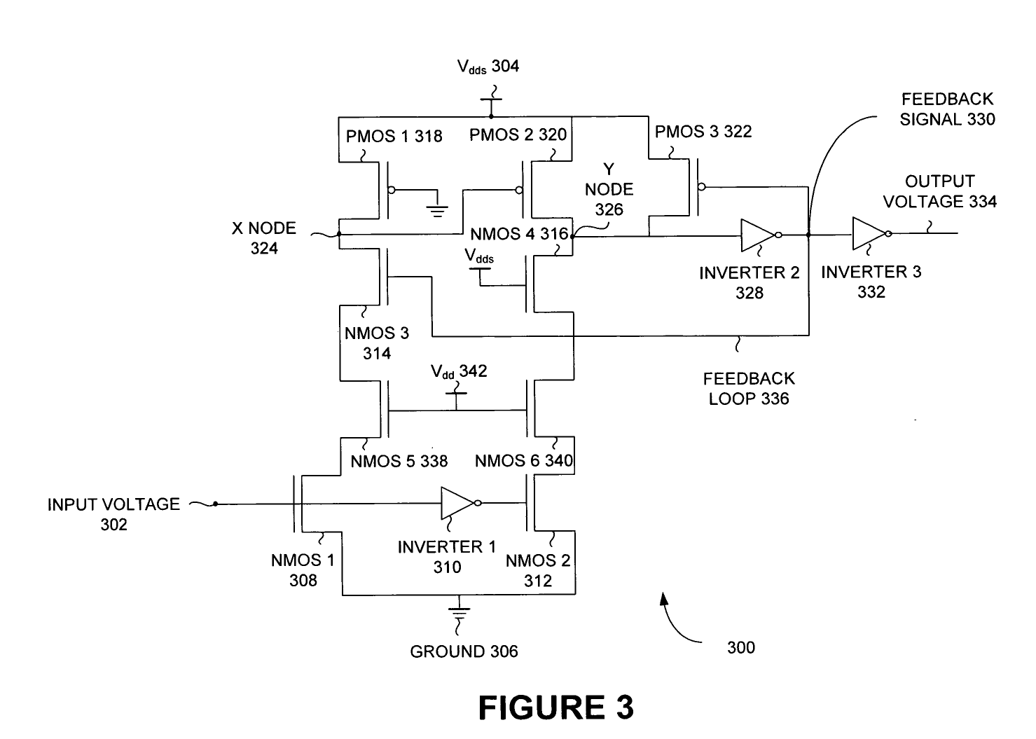

FIG. 3 is a voltage level shifter 300 which works with an I/O voltage being high while maintaining the benefits of the voltage level shifter 200 of FIG. 2, according to one embodiment. To remedy the shortcomings of the voltage level shifter 200 mentioned in FIG. 2, the voltage level shifter 300 allows a V_{dds} 304 to have a voltage up to 2.5 volts.

Most of the circuit of the voltage level shifter 300 is similar to the voltage level shifter 200 except that two extra thin oxide semiconductor field effect transistors, namely a NMOS 5 338 and a NMOS 6 340 are connected in series with a NMOS 1 308 and a NMOS 2 312, respectively. The NMOS 5 338 and the NMOS 6 340 are kept permanently on with their gates connected to a V_{dd} 342 (e.g., 1 volt). The NMOS 5 338 and the NMOS 6 340 protect the NMOS 1 308 and the NMOS 2 312 by preventing their gate to drain voltages from going above V_{dd}—the threshold voltage of the NMOS 1 308 and the NMOS 2 312 respectively, even when the V_{dds} 304 is 2.5 volts.

The NMOS 3 314 and the NMOS 4 316 (e.g., thick gate oxide semiconductor field effect transistor) protect the NMOS 5 338 and the NMOS 6 340. The gate oxide of the NMOS 5 338 and the NMOS 6 340 are never stressed as their gates are always connected to the V_{dd} 342. For V_{dds}=2.5 volts and V_{dd}=1 volt, the gate to drain voltage of the NMOS 5 338 and the NMOS 6 340 never goes above V_{dds}−V_{dd}—the threshold voltage of the NMOS 5 338 and the NMOS 6 340 respectively (e.g., 1.5 volts—the threshold voltage of the NMOS 5 338 or the NMOS 6 340).

The rest of the voltage level shifter 300 may work same as the voltage level shifter 200 of FIG. 2. The voltage level shifter 200 and the voltage level shifter 300 may perform better than the prior art shown in FIG. 1 in level shifting from the core voltage (e.g., 1 volt) to the I/O voltage (e.g., 2.5 volts). Slight modifications like replacing the PMOS 1 218 of FIG. 2 or the PMOS 1 318 of FIG. 3 with a resistor may be within the scope of present embodiments.

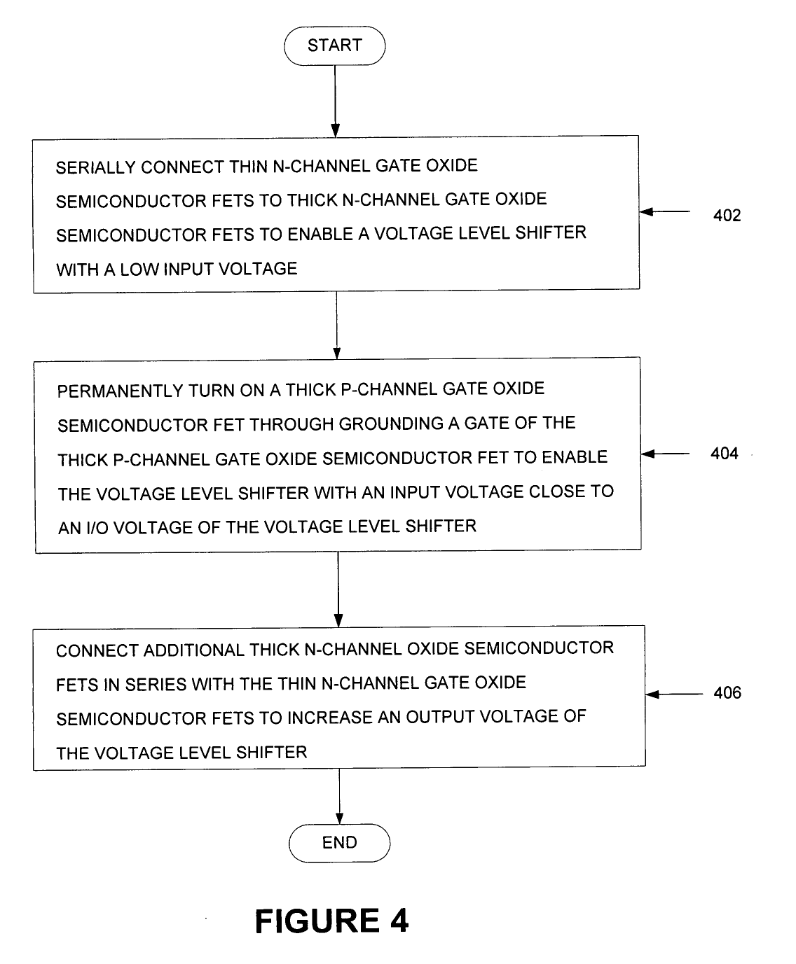

FIG. 4 is process flow chart of connecting gate oxide semiconductor FETs to enable a voltage level shifter with a wide range of input voltage, according to one embodiment. In operation 402, thin n-channel gate oxide semiconductor FETs (e.g., the NMOS 1 208 and/or the NMOS 2 212 of FIG. 2) are serially connected to thick n-channel gate oxide semiconductor FETs (e.g., the NMOS 3 214 and/or the NMOS 4 216) to enable a voltage level shifter (e.g., the voltage level shifter 200) with a low input voltage. In operation 404, a thick p-channel gate oxide semiconductor FET (e.g., the PMOS 1 218) is permanently turned on through grounding a gate of the thick p-channel gate oxide semiconductor FET to enable the voltage level shifter with an input voltage close to an I/O voltage of the voltage level shifter. In operation 406, additional thick n-channel oxide semiconductor FETs (e.g., the NMOS 5 338 and/or the NMOS 6 340 of FIG. 3) are connected in series with the thin n-channel gate oxide semiconductor FETs to increase an output voltage of the voltage level shifter.

Although the present embodiments have been described with reference to specific example embodiments, it will be evident that various modifications and changes may be made to these embodiments without departing from the broader spirit and scope of the various embodiments. It will be appreciated that the various embodiments discussed herein may/may not be the same embodiment, and may be grouped into various other embodiments not explicitly disclosed herein. Accordingly, the specification and drawings are to be regarded in an illustrative rather than a restrictive sense.

What is claimed is:

1. A voltage level shifter, comprising:
a plurality of gate oxide semiconductor field effect transistors (FETs) to translate an input voltage to an output voltage,
wherein a number of thin gate oxide semiconductor FETs of the plurality of gate oxide semiconductor FETs to connect with a number of thick gate oxide semiconductor FETs of the plurality of gate oxide semiconductor FETs.

2. The voltage level shifter of claim 1, wherein the plurality of gate oxide semiconductor FETs to comprise at least one of a p-channel gate oxide semiconductor FET and a n-channel gate oxide semiconductor FET.

3. The voltage level shifter of claim 1, wherein the number of thin gate oxide semiconductor FETs to enable the voltage level shifter to perform with the input voltage approximately at 0.9 volt.

4. The voltage level shifter of claim 1, further comprising a feedback loop to connect the output voltage of the voltage level shifter to one of the plurality of gate oxide semiconductor FETs to minimize power dissipation in the voltage level shifter.

5. The voltage level shifter of claim 1, further comprising at least one pair of thick gate oxide semiconductor FETs connected to the voltage level shifter with their gates connected to a low voltage supply to increase a limit of the output voltage.

6. The voltage level shifter of claim 5, wherein the low voltage supply supplies 1 volt and the limit of the output voltage is 2.5 volts.

7. A circuit, comprising:
a first transistor group to have a thick p-channel gate oxide FET, a thick n-channel gate oxide FET, and a thin n-channel gate oxide FET in series, wherein a gate of the thin n-channel gate oxide FET is connected to an input voltage, and a gate of the thick p-channel oxide FET is connected to a ground voltage;
a second transistor group to have a thick p-channel gate oxide FET, a thick n-channel gate oxide FET, and a thin n-channel gate oxide FET in series, wherein a gate of the thin n-channel gate oxide FET is connected to an inverse of the input voltage, a drain of the thick p-channel gate oxide FET of the first transistor group is connected to a gate of the thick p-channel gate oxide FET of the second transistor group, and a gate of the thick n-channel gate oxide FET is connected to an I/O voltage; and
a third transistor group to have a thick p-channel gate oxide FET, wherein a drain of the thick p-channel gate oxide FET is connected to a drain of the thick p-channel gate oxide FET of the second transistor group, and a gate of the thick p-channel gate oxide FET is connected to a feedback signal of the circuit; and
a feedback loop to connect the feedback signal to a gate of the thick n-channel gate oxide FET of the first transistor group.

8. The circuit of claim 7, wherein the I/O voltage is 1.8 volt and the input voltage is no less than 0.9 volt.

9. The circuit of claim 7, wherein the gate of the thick p-channel gate oxide FET of the first transistor group is connected to the ground voltage to enable the circuit to have the input voltage close to the I/O voltage.

10. The circuit of claim 7, wherein the thin n-channel gate oxide FET of the first transistor group and the thin n-channel gate oxide FET of the second transistor group to allow the circuit to have the input voltage of 0.9 volt.

11. The circuit of claim 7, further comprising a first inverter to inversely convert the input voltage to feed to the gate of the thin n-channel gate oxide FET of the second transistor group.

12. The circuit of claim 11, further comprising a second inverter to inversely convert a voltage obtained at the drain of the thick p-channel gate oxide FET of the second transistor group.

13. The circuit of claim 12, further comprising a third inverter to inversely convert the feedback signal to generate the output voltage.

14. The circuit of claim 13, further comprising a pair of additional thick n-channel gate oxide FETs added to the circuit to increase the I/O voltage.

15. The circuit of claim 14, further comprising a low voltage supply to connect to gates of the pair of additional thick n-channel gate oxide FETs.

16. The circuit of claim 15, wherein the low supply voltage supplies 1 volt to the gates of the pair of additional thick n-channel gate oxide FETs.

17. The circuit of claim 16, wherein the pair of additional thick n-channel gate oxide FETs to increase the I/O voltage up to 2.5 volts without aging the thin n-channel gate oxide FETs.

18. The circuit of claim 7, further comprising replacing the thick p-channel gate oxide FET of the first transistor group with at least one resistor.

19. A method of a voltage level shifter, comprising:
serially connecting thin n-channel gate oxide semiconductor FETs to thick n-channel gate oxide semiconductor FETs to enable the voltage level shifter with a low input voltage; and
permanently turning on a thick p-channel gate oxide semiconductor FET through grounding a gate of the thick p-channel gate oxide semiconductor FET to enable the voltage level shifter with an input voltage close to an I/O voltage of the voltage level shifter.

20. The method of claim 19, further comprising connecting additional thick n-channel oxide semiconductor FETs in series with the thin n-channel gate oxide semiconductor FETs to increase an output voltage of the voltage level shifter.
